(19) United States
(12) Patent Application Publication
(10) Pub. No.: US 2025/0331170 A1
(43) Pub. Date: Oct. 23, 2025

(54) SEMICONDUCTOR STRUCTURE AND METHOD OF FORMING THE SAME

(71) Applicant: NANYA TECHNOLOGY CORPORATION, New Taipei city (TW)

(72) Inventors: Yi-Ting TSAI, New Taipei City (TW); Wei-Ming LIAO, New Taipei City (TW)

(21) Appl. No.: 18/642,184

(22) Filed: Apr. 22, 2024

(51) Int. Cl. H10B 12/00; H01L 21/768; H01L 23/528; H01L 23/532

(52) U.S. Cl. CPC H10B 12/485; H01L 21/76883; H01L 23/5283; H01L 23/53271; H10B 12/482

(57) ABSTRACT

A semiconductor structure includes a plurality of bit-line structures laterally spaced apart on a substrate, a buried contact between the bit-line structures, and a landing pad on the buried contact. The buried contact includes a first conductive layer and a second conductive layer on the first conductive layer. The second conductive layer includes a main portion and a protruding portion extending from the main portion into the first conductive layer. A method of forming the semiconductor structure is also disclosed.

### BACKGROUND

### Field of Invention

The present invention relates to semiconductor structure and method of forming the same. More particularly, the present invention relates to dynamic random access memory (DRAM) and a method of forming the same.

### Description of Related Art

Through the advance in the technology, the pitches of the semiconductor structure in the DRAM become smaller with a high degree of integration to improve the performance of the DRAM. A distance of the elements in the semiconductor devices closer, makes the deposition in such shirking distance more difficult, e.g., forming the voids, which may increase the resistance, then degrades DRAM operation speed.

So that it is crucial to improve the DRAM performance and decrease the contact resistance in the forming of the semiconductor devices.

### SUMMARY

The invention provides a semiconductor structure. The semiconductor structure includes a plurality of bit-line structures laterally spaced apart on a substrate, a buried contact between the bit-line structures, and a landing pad on the buried contact. The buried contact further includes a first conductive layer, and a second conductive layer on the first conductive layer. The second conductive layer includes a main portion and a protruding portion extending from the main portion into the first conductive layer.

The invention provides a method of forming a semiconductor structure. The method includes forming a plurality of bit-line structures on a substrate, forming a trench in the substrate between the bit-line structures, forming a first conductive layer in the trench, and forming a second conductive layer on the first conductive layer. A material of the first conductive layer is different from a material of the second conductive layer. The second conductive layer further includes a main portion and a protruding portion extending from the main portion into the first conductive layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-6 are cross-sectional views of various formation stages of a method of forming a semiconductor structure according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It will be understood that, although the terms “first”, “second”, “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms, such as “lower” or “bottom” and “upper” or “top”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

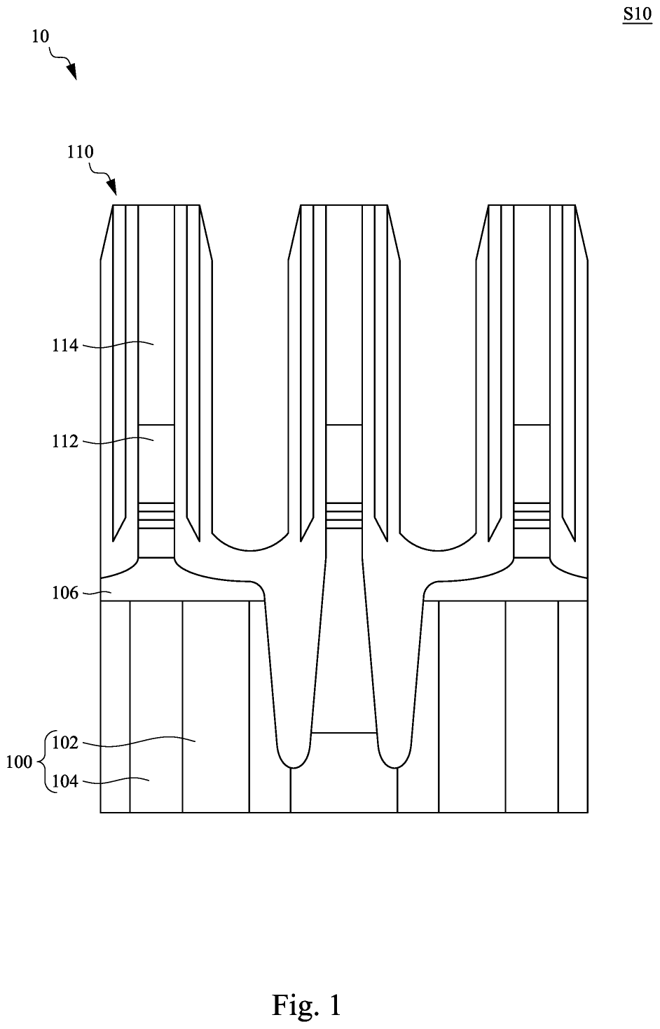

FIGS. 1-6 are cross-sectional views of various formation stages of a method of forming a semiconductor structure 10 according to some embodiments of the present disclosure.

Referring to FIG. 1, the method begins from step S10, a plurality of bit-line structures 110 are formed on the substrate 100. The semiconductor structure 10 includes a substrate 100. The substrate 100 further includes a plurality of active regions 102 and a plurality of isolation regions 104 spacing apart the active regions 102. An isolation layer 106 is formed on the substrate 100 and covers top surfaces of the active regions 102 and the isolation regions 104 for isolating the elements formed in sequence and the substrate 100. The bit-line structures 110 are spaced apart laterally from each other on the substrate 100. In some embodiments, each of the bit-line structure 110 through the direction vertical to the substrate 100 may include a conductive stack 112 and an insulation layer 114 on the conductive stack 112.

The substrate 100 may include silicon, such as crystalline silicon, polycrystalline silicon, or amorphous silicon). In some embodiments, the substrate 100 may include elementary semiconductor, an alloy semiconductor, or a compound semiconductor, or another suitable material. Further, the substrate 100 may optionally include a semiconductor-on-insulator (SOI) structure.

The substrate 100 may be performed an ion implantation process to dope n-type or p-type dopant. In some embodiments, a source/drain region is formed by doping a n-type or a p-type to the active region 102 of the substrate 100 (not shown in FIG. 1)

The isolation regions 104 may include at least one of silicon oxide, silicon nitride, and silicon oxynitride. The isolation region 104 may be a single layer or a multilayer. In some embodiments, the isolation regions 104 may be formed by shallow trench isolation (STI) process.

The isolation layer 106 may be formed by any suitable dielectric material, such as silicon oxide, silicon nitride, silicon oxynitride, tetraethylorthosilicate (TEOS) oxide, un-doped silicate glass (USG), borophosphosilicate glass (BPSG), fluorinated silicate glass (FSG), phosphosilicate glass (PSG), borosilicate glass (BSG), another suitable material, or a combination thereof.

The bit-line structures 110 are disposed on the substrate 100. In some embodiments, each of the bit-line structure 110 protrudes in the direction vertical to the substrate 100 and has a linear structure that extends along the direction (e.g., the direction of Y axis) parallel to the substrate 100 in accordance with FIG. 1.

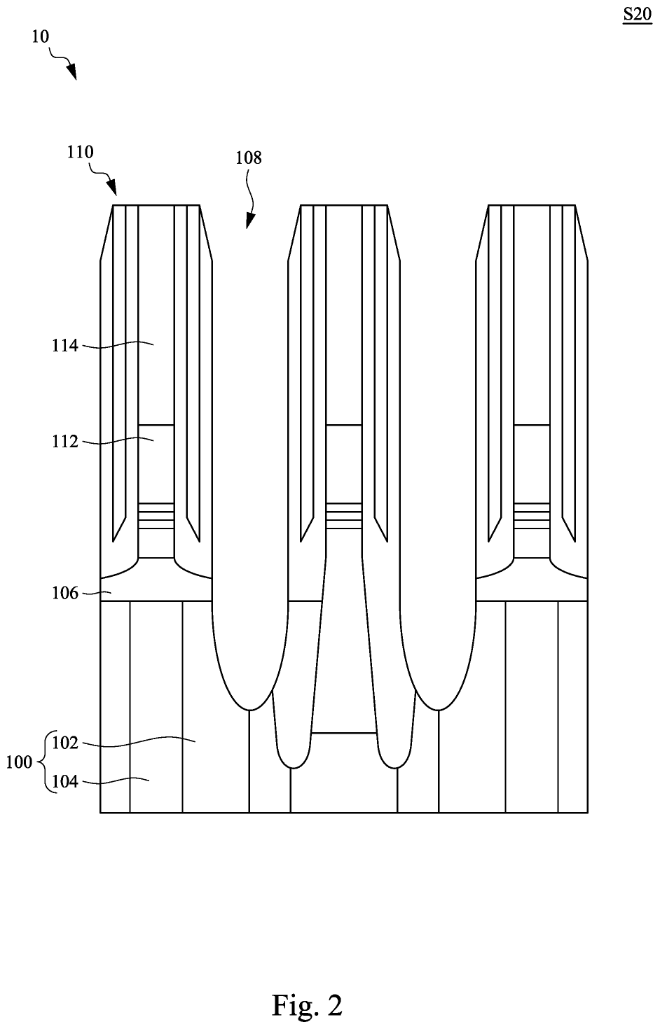

Referring to FIG. 2, the method goes to step S20, a plurality of trenches 108 are formed between the bit-line structures 110 on the substrate 100 and extend through the isolation layer 106 to expose portions of the active regions 102 of the substrate 100.

The trenches 108 are positioned along the direction vertical to the substrate 100. In some embodiments, bottom surfaces of the trenches 108 are lower than the isolation layers 106. The trenches 108 may expose the portion of the active regions 102 for electrically connecting the element (such as buried contacts 116 following formed) to the active regions 102.

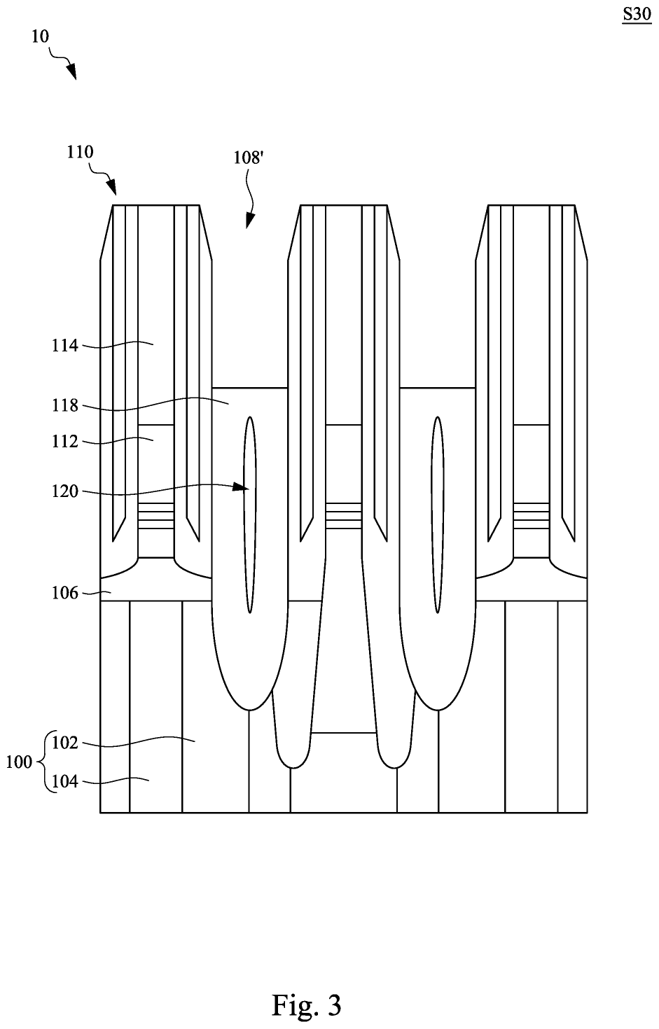

Referring to FIG. 3, the method goes to step S30, following formation of the trenches 108, a plurality of first conductive layers 118 are formed in the trenches 108. It is noticed that a material of the first conductive layers 118 is depositing in the trenches 108, while a plurality of voids 120 are formed inside the first conductive layers 118. Hence, each of the first conductive layers 118 further includes the void 120. Due to the evolution of the semiconductor structures, the size of the semiconductor structure becomes smaller, causing the trenches with higher aspect ratio than before. Depositing a material in the trenches with such higher aspect ratio may easily form the voids. It is worth mentioning that the formation of the voids may induce the contact resistance of the semiconductor structure and further degrade the operation speed of DRAM. Generally, the void should be avoided in the formation of the semiconductor structure.

The material of the first conductive layers 118 is filled into a portion of each of the trenches 108 between the bit-line structures 110. Upper portions of the first conductive layers 118 above the isolation layer 106 are surrounded by the bit-line structures 110. In some embodiments, top surfaces of the first conductive layers 118 are higher than top surfaces of the conductive stacks 112, but lower than top surfaces of the bit-line structures 110.

In some embodiments, the material of the first conductive layers 118 may be deposited by any suitable operations, like chemical vapor deposition (CVD), atomic layer deposition (ALD), physical vapor deposition (PVD) or the like. In addition, the material of the first conductive layers may be any suitable conductive material, such as polysilicon.

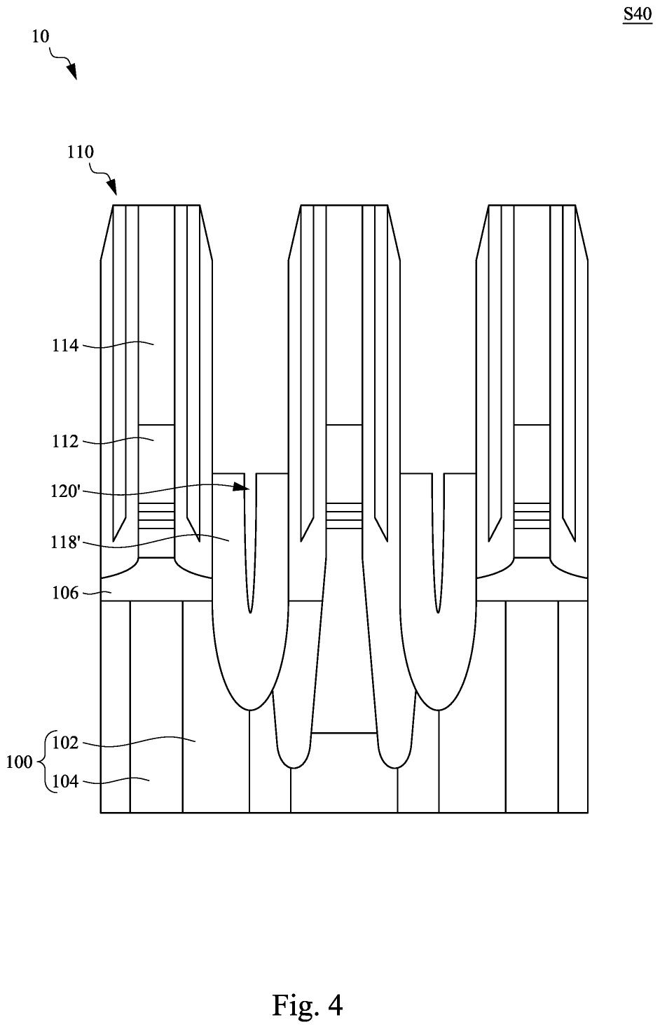

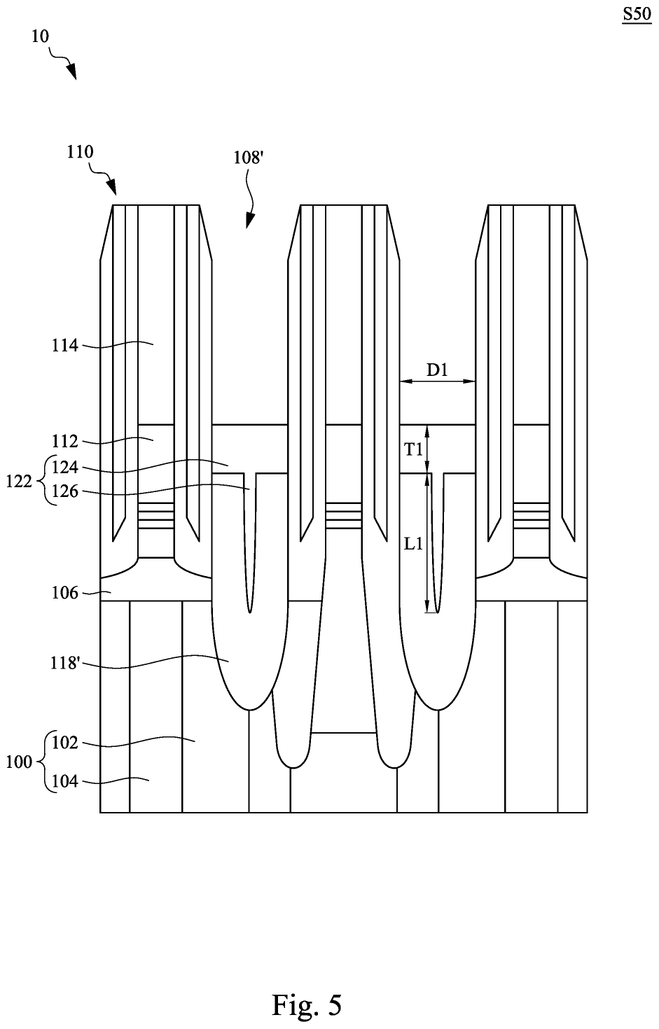

The voids 120 are formed with an elongated shape along the direction of the trenches 108 inside the first conductive layers 118. In some embodiment, two end of each of the voids 120 may be a sharp, rounded, or blunt profile, or the like. Each of the voids 120 is surrounded by each of the first conductive layers 118. A Portion of each of the first conductive layers 118 covers on a top portion of each of the voids 120. In such way, the voids 120 does not expose to the air. For avoiding the existence of the void 120, a top portion of the material of the first conductive layer 118 is removed, exposing the voids 120, followed by a formation of a plurality of second conductive layers 122 on the first conductive layers 118 with reference to FIGS. 4-5.

Referring to FIG. 4, the method goes to step S40, following formation of the first conductive layers 118, a top portion of the material of the first conductive layers 118 is removed to form the first conductive layers 118′ and expose the voids 120′.

The voids 120′ are exposed and merely surrounded by the first conductive layers 118′. In some embodiment, the top surfaces of the first conductive layers 118′ are lower than the top surfaces of the conductive stacks 112. In some embodiments, the removal of the top portion of the material of the first conductive layers 118 may include any suitable etch process, such as dry etch, and/or wet etch, or the like.

Referring to FIG. 5, the method goes to step S50, following removal of the top portion of the material of the first conductive layer 118, the second conductive layers 122 are formed on the first conductive layers 118′. The second conductive layers 122 are disposed on the first conductive layers 118′ and further filled into the voids 120′ (as shown in FIG. 4) for eliminating the voids 120′ and improving the contact resistance. In some embodiments, the voids 120′ are full of the second conductive layers 122 without any space.

Each of the second conductive layers 122 further includes a main portion 124 and a protruding portion 126 from the main portion 124 and extending into each of the first conductive layer 118′. The main portions 124 cover the first conductive layers 118′. In some embodiments, top surfaces of the main portions 124 are coplanar to the top surfaces of the conductive stacks 112. The protruding portions 126 are formed by filling the second conductive layers 122 into the voids 120′. The protruding portions 126 are surrounded and in contact with the first conductive layers 118′. For examples, each of the main portions 124 has a vertical thickness T1 in the direction vertical to the substrate 100. The vertical thickness T1 of the main portions 124 are between about 5 nm and about 10 nm. Each of the protruding portions 126 has a vertical length L1 in the direction vertical to the substrate 100. The vertical length L1 of the protruding portions 126 are between about 20 nm and about 50 nm. Further, each of the first conductive layers 118′ has a diameter D1 in the plane that parallels to the substrate 100. The vertical length L1 of the protruding portions 126 are about 0.6 times to about 1.5 times to the diameter D1 of the first conductive layers 118′.

The material of the first conductive layers 118′ may be the same as or different from that of the second conductive layers 122. In some embodiments, the material of the first conductive layers 118′ is the same as the material (e.g. polysilicon) of the second conductive layers 122. Although the voids 120′ are eliminated by filling the same material, it still induces higher contact resistance. In some embodiment, the material of the first conductive layers 118′ is different from the material of the second conductive layers 122. For example, the first conductive layer 118′ may include polysilicon, and the second conductive layer 122 may include cobalt. A resistivity of the material of the second conductive layers 122 is lower than a resistivity of the material of the first conductive layers 118′. Namely, the resistivity of the second conductive layers 122 is lower than a resistivity of the first conductive layers 118′. In such way, depositing the lower resistivity of the material of the second conductive layers 122 instead of the same material as the first conductive layers 118′ into the voids 120′, the contact resistance may be further reduced due to more conductive material. Hence, the operation speed of the DRAM may be improved. In some embodiments, the material of the second conductive layers 122 may be deposited by other suitable operations, like CVD, ALD, PVD or the like.

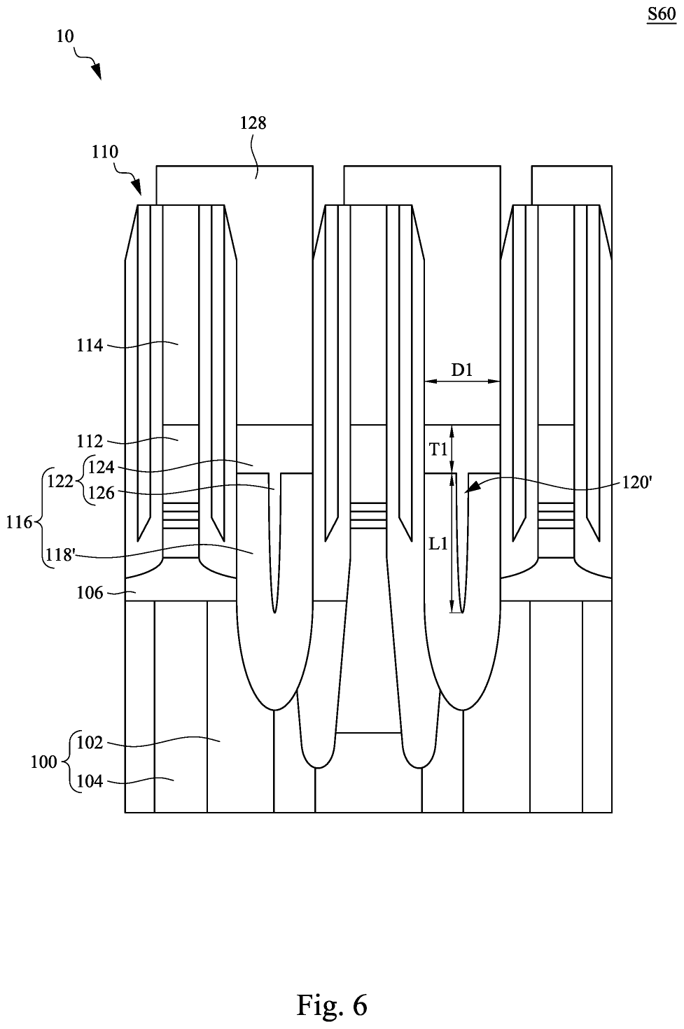

Referring to FIG. 6, the method goes to step S60, following formation of the second conductive layers 122, a plurality of landing pads 128 are formed on the second conductive layers 122 between the bit-line structures 110 and cover portions of the bit-line structures 110.

The landing pads 128 are deposited to fill the rest of the trenches 108′ between the bit-line structures 110. Top surfaces of the landing pads 128 are higher than the top surfaces of the bit-line structures 110. Bottom surfaces of the landing pads 128 contact the top surfaces of the second conductive layers 122. Side walls of the landing pads 128 in the trenches 108′ are in contact with side walls of the bit-line structures 110.

In some embodiments, a material of the landing pads 128 may include conductive material, such as tungsten, copper, aluminum, alloy or other suitable conductive material. The material of the landing pads 128 may be deposited as a blanket layer. The deposition operation may include any suitable deposition operation, such as CVD, PVD, ALD, or the like.

The semiconductor structure 10 is formed by the method of forming the semiconductor structure is provided in FIG. 6. The semiconductor structure 10 includes the substrate 100, which includes the active regions 102 and the isolation regions 104 spacing apart the active regions 102. The isolation layer 106 is disposed on top surfaces of the active regions 102 and the isolation regions 104. A plurality of bit-line structures 110 are laterally positioned on the isolation layer 106 on the substrate, and space apart from each other. The buried contacts 116 are disposed between the bit-line structures 110, and the landing pads 128 are formed on the buried contacts 116, covering the portions of the bit-line structures 110.

Each of the bit-line structures 110 includes the conductive stack 112 and the insulation layer 114 on the conductive stack 112 in a plane vertical to the substrate 100 in accordance with FIG. 6. The bottom portions of the buried contacts 116 are embedded in the substrate 100 and partially in contact with the active regions 102.

Each of the buried contact 116 further includes the first conductive layer 118′ and the second conductive layer 122 on the first conductive layer 118′ in a cross-section view in the plane vertical to the substrate 100. The first conductive layers 118′ include the voids 120′ extending from the top surfaces of the first conductive layers 118. The second conductive layers 122 are disposed on and filled into the first conductive layers 118′ for eliminating the voids 120′. Due to the existence of the voids 120, the contact resistance of the semiconductor structure 10 may be increased. Each of the second conductive layers 122 further includes the main portion 124 and the protruding portion 126. The protruding portions 126 extend from the main portions 124 and into the first conductive layers 118. Namely, the bottom surfaces of the main portions 124 are contact with the top surfaces of the first conductive layers 118′. The protruding portions 126 are surrounded and in contact with the first conductive layers 118′. In some embodiments, the top surfaces of the main portions 124 and the top surfaces of the conductive stacks 112 are coplanar.

In the plane vertical to the substrate 100, each of the main portions 124 has a vertical thickness T1 and each of the protruding portions 126 has a vertical length L1. In some embodiments, the vertical thickness T1 of the main portion 124 is between about 5 nm and about 10 nm. The vertical length L1 of the protruding portion 126 is between about 20 nm and about 50 nm. Further, in the plane that is parallel to the substrate 100, a cross section view of each of the first conductive layer 118′ has a diameter D1. In some embodiments, the diameter is uniform through the buried contact 116. The vertical length L1 of the protruding portion 126 is about 0.6 times to about 1.5 times to the diameter D1 of the first conductive layer 118′.

A material of the second conductive layers 122 may be deposited on the first conductive layers 118′. In addition, the material of the second conductive layers 122 may be the same as or different from the material of the first conductive layers 118′. In some embodiments, the material of the first conductive layers 118′ may be selected for polysilicon and the material of second conductive layers 122 may be selected for cobalt, so that the resistivity of the second conductive layers 122 is lower than the resistivity of the first conductive layers 118′. The lower resistivity material used in the second conductive layers 122 may reduce the contact resistance to further improve the operation speed of the DRAM.

The landing pads 128 are disposed on the buried contacts 116 as shown in FIG. 6. The landing pads 128 may electrically connect to the buried contacts 116, and further to storage nodes/capacities of bottom electrodes (not shown) in according to the active regions 102. Namely, the storage nodes/capacities of the bottom electrodes (not shown) electrically connect to the active regions 102 with the buried contacts 116.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor structure, comprising:
a plurality of bit-line structures laterally spaced apart on a substrate;
a buried contact between the bit-line structures, wherein the buried contact comprises:
a first conductive layer; and
a second conductive layer on the first conductive layer, wherein the second conductive layer comprises:
a main portion; and
a protruding portion extending from the main portion into the first conductive layer; and
a landing pad on the buried contact.

2. The semiconductor structure of claim 1, wherein the first conductive layer surrounds and is in contact with the protruding portion.

3. The semiconductor structure of claim 1, wherein a resistivity of the second conductive layer is lower than a resistivity of the first conductive layer.

4. The semiconductor structure of claim 1, wherein the second conductive layer comprises cobalt, and the first conductive layer comprises polysilicon.

5. The semiconductor structure of claim 1, wherein a vertical thickness of the main portion is between 5 nm and 10 nm.

6. The semiconductor structure of claim 1, wherein a vertical length of the protruding portion is between 20 nm and 50 nm.

7. The semiconductor structure of claim 1, wherein a vertical length of the protruding portion is 0.6 times to 1.5 times a diameter of the first conductive layer.

8. The semiconductor structure of claim 1, wherein the substrate comprises an active region, the buried contact is partially embedded in the substrate and in contact with the active region.

9. The semiconductor structure of claim 1, wherein each of the bit-line structures comprises a conductive stack and an insulation layer on the conductive stack, and a top surface of the conductive stack is substantially coplanar to a top surface of the second conductive layer.

10. A method of forming a semiconductor structure, comprising:
forming a plurality of bit-line structures on a substrate;
forming a trench in the substrate between the bit-line structures;
forming a first conductive layer in the trench; and
forming a second conductive layer on the first conductive layer, wherein a material of the first conductive layer is different from a material of the second conductive layer, and the second conductive layer comprises:
a main portion; and
a protruding portion extending from the main portion into the first conductive layer.

11. The method of claim 10, wherein forming the first conductive layer in the trench comprises:
depositing the material of the first conductive layer in the trench, wherein a void is formed inside the material of the first conductive layer; and
removing a top portion of the material of the first conductive layer to expose the void.

12. The method of claim 11, wherein removing the top portion of the material of the first conductive layer to expose the void is performed by dry etching.

13. The method of claim 11, wherein forming the second conductive layer on the first conductive layer comprises:
depositing the material of the second conductive layer to cover the first conductive layer and to fill the void.

14. The method of claim 10, wherein a resistivity of the second conductive layer is lower than a resistivity of the first conductive layer.

15. The method of claim 10, further comprises forming a landing pad on the second conductive layer.

16. The method of claim 10, wherein forming the trench in the substrate between the bit-line structures comprises:
etching the substrate to form the trench between the bit-line structures, exposing an active region of the substrate.
